(19) United States
(12) Patent Application Publication
(10) Pub. No.: US 2008/0038579 A1
(43) Pub. Date: Feb. 14, 2008

(54) Metal Product, Method of Manufacturing a Metal Product and Use Thereof

(76) Inventors: Mikael Schuisky, Sandviken (SE); Ulrika Isaksson, Sandviken (SE)

Correspondence Address: DRINKER BIDDLE & REATH (DC), 1500 K STREET, N.W., SUITE 1100, WASHINGTON, DC, 20005-1209, US

(21) Appl. No.: 11/660,138

(22) PCT Filed: Aug. 25, 2005
(86) PCT No.: PCT/SE05/01245

§ 371 Date: Aug. 1, 2007

(30) Foreign Application Priority Data
Aug. 25, 2004 (SE) 0402082-2

(51) Int. Cl. B32B 15/00; C23C 16/00

(52) U.S. Cl. 428/640; 427/251

(57) ABSTRACT

A metal product having a metallic substrate in the form of a tube, strip, foil wire, fibre or bar has a decorative coating consisting of at least two different layers. One layer is based on a metal or metal alloy and one layer is based on a transparent oxide. The product is produced with the aid of PVD in a continuous process and is used in various customer-related products, such as household equipment, mobile phones, or buttons and zippers in clothing.

The following disclosure relates to a metal product consisting of a metallic substrate and a coating. The coating comprises at least two separate layers wherein one consists of a metal or metal alloy, and one consists of a transparent oxide. Furthermore, the present disclosure relates to a method of manufacturing such a product and use of such a product in the manufacturing of applications requiring a decorative surface.

### BACKGROUND TO THE INVENTION AND PRIOR ART

Metallic products, e.g. in the form of strips, wires etc., with decorative surfaces accomplished by coatings, can be used in various applications. Some examples are outdoor life applications, sports and sealife applications. They can also be used in household applications, door handles, cameras, mobile phones and other telecom applications. Moreover, they can be used as food packages. Furthermore, various knife and saw applications can be use metallic strips with decorative coatings. Yet another application is in shaving equipment or in personal belongings like watches, glasses, cosmetic applications, caps for perfume bottles, or buttons and zippers in clothing.

It is important that the coating has a very good adhesion to the substrate. In some of the applications above there may be a high risk of a coating on a metal substrate to flake off or fissure. Furthermore, they may be used in corrosive environments. It is therefore also important to have a coating that is corrosion resistant. Moreover, it is important that the coating does not discolour during usage. For example, in the case of food package applications, a discoloured surface may result in a loss of sale of the food product since the customer will automatically think there is something wrong with the food product as well. Also, in some cases there may be requirements of a coating having a thickness that is uniform, i.e. applications requiring small tolerances in thickness of the coating or even of the product itself.

Furthermore, due to economic reasons it is preferred if the strip can be produced in a continuous roll-to-roll process and that the final product is manufactured from the produced metal strip. Therefore, it is important that the coating also is able to withstand further slitting operations, stamping and/or forming, as well as cleaning processes like hot water degreasing.

There are several common methods of making a decorative surface finish on metallic materials. As examples can be mentioned:
Anodising is a known method that can be used for various colours. Normally this method is used on aluminium or aluminium alloys, but may also be used on magnesium, zinc and titanium. The aluminium is made the anode of an electrolysis cell using an aqueous acid electrolyte for a few minutes at comparatively low current densities. The resulting oxide film is usually 5-25 μm thick and makes the aluminium for example more resistant to corrosion and wear resistant. The film can also be dyed with colouring matter since it is porous and absorbent. Colours like black, blue, red, purple, and green can be accomplished, however, the most common surfaces are uncoloured. A wide variety of anodised finishes are found on the aluminium parts of small appliances and household siding. However, an obvious drawback is that it is not possible to use directly on for example stainless steels.
Vapour deposition methods are used in some cases for colouring of metallic products. Often the colour is produced by applying a metal nitride to the surface of the component. However, most methods are batch-like processes, which means that the coating is done on the finished component piece by piece. One obvious drawback with such a method is that it is not continuous, and thus also very expensive to use. One example of batch coating on consumer related products is revealed in U.S. Pat. No. 6,197,438 B1 (hereby incorporated into the present disclosure by this reference) where ceramic coated food wares are coated with silicon nitride, aluminium or diamond-like carbon for a decorative effect i.e. create lacquered surface appearance. More examples of decorative coatings by batch PVD are disclosed in U.S. Pat. No. 5,510,012, in which a decorative gold colour is applied in a batch process by cathode sputtering of gold-vanadium alloy in a nitrogen atmosphere and also in EP-A=1 033 416, in which a decorative bronze colour is achieved by batch PVD.
One commonly used method is painting of the metallic surface with coloured lacquers, or the like. However, in most painting processes the painting is done on the finished component piece by piece. One obvious drawback with such a method is that it is not a continuous roll-to-roll process, and thus also quite expensive to use. A continuous painting process is normally not possible to use since the adhesion usually is not good enough for further processing in, e.g., forming operations without causing defects or flaking in the surface. Also, paints can normally not withstand further heat treatments.

Consequently, the coatings and the processes for their manufacturing stated above can not be used for the present invention in order to provide a decorative surface on a metallic substrate.

Therefore, it is a primary object of the invention to provide a decorative surface on a metallic substrate by the usage of a coating.

A further object of the invention is to accomplish a coating, which has a good adhesion to a metallic substrate.

A further object of the invention is to obtain a cost-efficient decorative coating on a metallic substrate that can be deposited in a continuous roll-to-roll process.

Another object of the invention is to accomplish a coating that has a thickness that is as uniform as possible, on a metal substrate.

Yet another object of the invention is to provide a metal product having a decorative surface while at the same time having good formability, so as to enable manufacturing of customer related applications of said metal product.

### SUMMARY OF THE INVENTION

The present invention relates to a metal product having a substrate of a metallic material and a decorative coating. The invention also relates to the production of such a metal product in a continuous roll-to-roll process using PVD.

The decorative coating is achieved by applying at least one layer of a metal or a metal alloy and one layer of a transparent oxide onto a metallic substrate. The metal or metal alloy layer may preferably be located between the substrate and the transparent oxide. The coating may also include further layers, such as further metal layers or layers of oxides, nitrides, carbides, or mixtures thereof.

The decorative coating is deposited by means of Physical Vapour Deposition (PVD) in a roll-to-roll process, to an evenly distributed layer with a thickness of less than 15 μm, preferably less than 10 μm, most preferably less than 5 μm. The preferred PVD methods to be used are either electron beam evaporation (EB) of sputtering. The EB-evaporation process is well known to a person skilled in the art and is, e.g., comprehensively described in the book Electron Beam Technology by Siegfried Schiller, Ullrich Heisig and Siegfried Panzer, Verlag Technik GmbH Berlin 1995, ISBN 3-341-01153-6 and both sputtering and evaporation are also comprehensively well described in chapter 3 in the book The Materials Science of Thin Films by Milton Ohring, Academic Press, Boston 1992, ISBN 0-12-524990-X, both being hereby incorporated into the present disclosure by these references.

It has now been discovered that it is possible to make decorative surfaces on metallic substrates, for example strips of stainless steel, by the use of a coating having at least two layers wherein one consists of a metal or metal alloy, and one consists of a transparent oxide.

The product is produced in a continuous roll-to-roll process with a minimum speed of 10 meters per minute, preferably at least 25 m/min, included in a production line using PVD and comprising an etch chamber in-line.

### BRIEF DESCRIPTION OF THE DRAWINGS

FIG. 1 Schematic view of a metal substrate with a coating according to the invention.

FIG. 2 Schematic illustration of the CIE L*a*b* colour space.

### DETAILED DESCRIPTION OF THE INVENTION

Metal substrate

The metal substrate can be in the form of a fibre, wire, strip, foil, bar, or tube. One preferred embodiment is when the substrate is in the form of a foil or strip.

Furthermore, it should have a good basic corrosion resistance. Therefore, the metal substrate can for example be a stainless steel with a Cr content of at least 10% by weight depending on the other alloying elements of the steel. Other examples of substrate material can be Ni or Ni-based alloys, Al or Al-based alloys, Cu or Cu-based alloys and Ti or Ti-based alloys. The metal substrate material should also have good formability since it should be possible to process the substrate further after coating, to get the final product its desired shape and properties. Possible processes may be for example forming, deep drawing, punching, stamping, heat treatment etc.

Examples of suitable stainless steels are ferritic chromium steels of the type AISI 400-series, austenitic stainless steels of the type 300-series, hardenable chromium steels, duplex stainless steels, or precipitation hardenable stainless steels. Also other stainless grades such as cobalt alloyed steels or high Ni alloys can be used. Furthermore, alloys based on Al, Ti, Cu or Ni may also be used.

Naturally, the substrate material has to be adapted to the specific application of the final product. Parameters like tensile strength, fatigue strength, hardness, geometrical shape etc. has to be brought in line with the specific requirements of the final product. For example, in the case of knife applications, the substrate is preferably in the form of a strip and it has to be able to withstand the material in which they will operate, i.e. cut.

If the substrate is for example in the form of a strip it can preferably be up to 1500 mm in width, have a strip thickness of usually less than 5 mm, preferably less than 3 mm, and be at least 100 m long. The quality of the final product can be guaranteed at strip lengths of least up to 5 km, as a result of the coating process used. Preferably, the width and the thickness of the strip are selected to be a width and a thickness suitable for manufacturing the final width of the intended final product.

Coating

The coating according to the invention consists of at least two different layers. One layer is a metal layer of 5 nm-5 μm, preferably 100 nm-2 μm. The other layer is a layer of a transparent oxide with a thickness of 5 nm-5 μm, preferably 10 nm-2 μm.

The coating has a good adhesion to the metal substrate, thereby avoiding that it flakes off or fissures especially if the metal substrate has to be processed further, for example by forming or heat treatment of some kind. Also, the coating is uniform. In fact, the thickness can be controlled within the range of ±10%.

A tight tolerance in layer thickness is also of advantage for achieving a consistency in appearance of the coating, for example in colour. Thus, thanks to the high coating thickness tolerances, a superior colour consistency has been achieved, even on long substrates such as 5 km and even longer. These long substrates have been made possible thanks to the relatively high feed velocities.

Both one-sided coatings and two-sided coatings can be used. From an economical point of view it is preferred that only one-sided coatings are used for the applications where it is applicable, i.e. where only one surface is required to appear decorative.

The coating consists of at least two layers, as stated above. One layer is a metal or metal alloy layer and the other is a layer of a transparent oxide. Examples of transparent oxides are MgO, Al₂O₃, TiO₂ and SiO₂. The metallic layer consists of one of the following metals: Ag, Al, Au, Co, Cu, Fe, Mn, Si, Sn, Ti, V, W, Zn, Zr or alloys thereof, like for example Bronze or Brass.

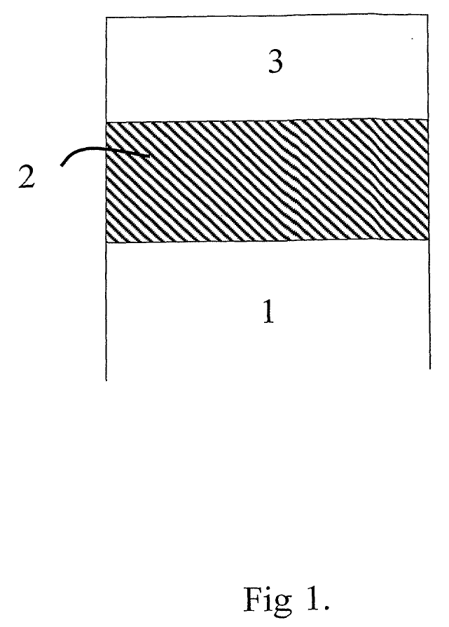

Furthermore, according to one preferred embodiment, which is illustrated in FIG. 1, the metallic layer 2 is located between the metallic substrate 1 and the transparent oxide layer 3. According to another preferred embodiment is the metallic layer thicker than the layer of the transparent oxide.

The coating may also include further layers in addition to the two layers stated above. These additional layers may be of the same or of a different composition. For example, a layer of another metal or metal alloy may be a part of the coating. Furthermore, layers of oxides, nitrides, carbides, or mixtures thereof can be included in the coating. These additional layers may be located anywhere in the coating, but preferably not outside the transparent oxide layer.

The present disclosure is primarily suitable for relatively thin coatings. The coatings are usually not more than 15 μm in total on each side of the substrate. Normally, they are up to 10 μm in total, preferably up to 5 μm.

In the case where the oxide is located outside of the metal layer the colour of the metal layer will shine through the oxide and thereby contribute to the colour of the coating. Also, an advantage of using a transparent oxide layer is that one might get a more vivid appearance due to interference in the oxide layer.

Furthermore, the transparent oxide as well as the metallic layer may contribute to further requirements of the coating, for example wear resistance, corrosion resistance or hardness.

In addition to the different layers above, the metallic substrate with the coating may also be painted or lacquered if so is required, for example by the final application for which the final product should be used. This could be performed directly after the coating but can also be performed after additional treatment steps like for example heat treatment or forming. The paint/lacquer could for example be added to the coated surface when the substrate has been formed into a final product, for example a watch or a razor blade. The purpose of the paint/lacquer may be to provide additional resistance to corrosion or perhaps additional protection during transportation of the coated metal substrate.

Coating Process

A variety of physical or chemical evaporation deposition methods for the application of the coating media and the coating process may be used as long as they provide a continuous uniform and adherent layer. As exemplary of deposition methods can be mentioned chemical vapour deposition (CVD), metal organic chemical vapour deposition (MOCVD), physical vapour deposition (PVD) such as sputtering and evaporation by resistive heating, by electron beam, by induction, by arc resistance or by laser deposition methods, but for the present invention especially two PVD methods are preferred for the deposition, either electron beam evaporation (EB) or sputtering. Optionally, the EB evaporation can be plasma activated to even further ensure good quality coatings of dense and decorative layers.

An advantage by the use of PVD technique is that very thin layers/coatings can be deposited on the strip and that it can be performed in a continuous way, while still achieving superior adhesion and uniformity. The tolerance of the thickness of the coating may be as low as ±10%, as mentioned earlier.

For the present invention, it is a pre-requisite that the coating method is integrated in a roll-to-roll production line with a minimum substrate speed of 10 m/min, preferably min 25 m/min, to achieve a cost efficient productivity and also to be able to maintain the properties of the substrate material by minimising the heat influence, which otherwise would risk to deteriorate the properties of the end-product. The coating layer is then deposited by means of PVD, such as electron beam evaporation (EB) or by sputtering, in a roll-to-roll process. The formation of the different layers can be achieved by integrating several deposition chambers in-line. The deposition of metallic layers should be made under reduced atmosphere at a maximum pressure of 1×10⁻² mbar with no addition of any reactive gas to ensure essentially pure metal films. The deposition of metal oxides should be performed under reduced pressure with an addition of an oxygen source as reactive gas in the chamber. A partial pressure of oxygen should be in the range 1-100×10⁻⁴ mbar. If other types of coatings are to be achieved, e.g., metal carbides and/or nitrides such as for example TiN, TiC or CrN, or mixtures thereof, the conditions during the coating should be adjusted with regard to the partial pressure of a reactive gas so as to enable the formation of the intended compound. In the case of oxygen, a reactive gas such as H₂O, O₂ or O₃, but preferably 02, may be used. In the case of nitrogen a reactive gas such as N₂, NH₃ or N₂H₄, but preferably N₂, may be used. In the case of carbon, any carbon containing gas may be used as reactive gas, for an example CH₄, C₂H₂ or C₂H₄.

To enable a good adhesion, different types of cleaning steps are used. First of all, the surface of the substrate material should be cleaned in a proper way to remove all oil residues, which otherwise may negatively affect the efficiency of the coating process and the adhesion and quality of the coating. Moreover, the very thin native oxide layer that normally always is present on for example a steel surface must be removed. This can preferably be done by including a pre-treatment of the surface before the deposition of the coating. In this roll-to-roll production line, the first production step is therefore preferably an ion assisted etching of the metallic surface to achieve good adhesion of the first layer.

As mentioned earlier, the strip speed is at least 10 meters per minute, preferably at least 25 m/min, but may be performed at much higher velocities also.

The decorative coating may also be produced in several steps. In this case, the whole substrate is first coated with one layer and thereafter coated one of more additional times with new layers. The different layers may be of the same or a different composition, as long as one layer is a metal or metal alloy, and one layer is a transparent oxide. Furthermore, the coating can also be performed in several separate chambers in-line wherein a different layer of the coating is applied in each chamber. Also, in this case the different layers may be of the same composition or of different compositions.

Moreover, the belt may be cooled by special cooling means at the same time as it is coated, the cooling taking place on the side of the belt opposed to the side being coated. Thereby, the heat influence on the belt may be controlled, so that the properties of the substrate are substantially maintained.

In the case where the substrate is to be coated on both sides, this process can be performed on one side at a time or both sides at the same time.

As mentioned earlier, the substrate may also be painted or lacquered after the coating process. The purpose of this extra coating layer may for example be protection during transportation or of the environment that a final product is to be working in.

The invention will now be explained in more detail by the use of some examples. These examples are not to be seen as limiting of the invention, but merely of illustrative nature. The examples will illustrate the substrate in the form of a strip, this is however merely for the simplicity of making such a shape. The substrates can also be made in the form of a foil, fibre, wire, bar or tube.

### EXAMPLE 1

A Sample 1 in the form of a 0.10 mm thick strip of a stainless steel coated with a layer of Cu and thereafter with a layer of TiO₂ was produced according to the method stated above. The substrate material had the following composition: 0.7% C, 0.4% Si, 0.7% Mn, max 0.025% P, max 0.010% S, 13% Cr. The thickness of Cu was approximately 0.5 μm and the thickness of TiO₂ was approximately 22 nm.

A bending test was performed according to standard SS-EN ISO 7438 in order to test the adhesion of the coating to the substrate. The minimum bending radius was equal to the thickness of the strip and the bending test was performed over 90°. Furthermore, the test was performed three times for each radius and both perpendicular and parallel to the coating direction. The results are shown in Table 1, wherein in W means that the tested strip is whole and the coating is showing no tendency of flaking or the like, C means that the substrate showed cracks and B means that the substrate broke.

TABLE 1

| | Radius | | | | | |
|---|---|---|---|---|---|---|
| | 0.10 | 0.16 | 0.25 | 0.50 | 0.80 | 1.00 |
| Direction | mm | mm | mm | mm | mm | mm |
| Parallel | — | — | B | C | 1 W | W |
| | | | | | 2 C | |
| Perpendicular | W | W | W | — | — | — |

The reason for the break/cracks of the samples when tested (over radius 0.25, 0.50 and 0.80) parallel to the coating direction is that the coating direction in this case was the same as the direction of rolling of the strip and that the substrate itself did not withstand the bending test since it was in a cold-rolled condition. However, the coatings did not show any tendency of flaking or the like in these tests either.

### EXAMPLE 2

The colour of Sample 1 according to Example 1 was tested with the aid of CIE Lab whereby the colour can be described in L*, a* and b* values. Furthermore, additional samples based on the same substrate as Sample 1 and with coatings according to Table 2 were tested the same way.

TABLE 2

| Sample | Thickness Cu (μm) | Thickness TiO₂ (nm) |
|---|---|---|
| 2 | 0.5 | 30 |
| 3 | 0.5 | 36 |
| 4 | 0.5 | 17 |

CIE, the International Commission on Illumination—abbreviated as CIE from the its French title Commission Internationale d'Éclairage—is an organisation devoted to international co-operation and exchange of information among its member countries on all matters relating to science and art of lighting.

CIE standardised the XYZ values as tristimulus values that describe any colour that can be perceived by an average human observer. These primaries are nonreal, i.e. they cannot be realised by actual colour stimuli This colour space is chosen in such a way that every perceptible visual stimulus be described with positive XYZ values. A very important attribute of the CIE XYZ colour space is that it is device independent.

The transformation from CIE XYZ to CIE Lab is performed with following equations

$${L}^{*} = 116 {( \frac{Y}{Yn} )}^{\frac{1}{3}} - 16$$

$${a}^{*} = 500 [ {( \frac{X}{Xn} )}^{\frac{1}{3}} - {( \frac{Y}{Yn} )}^{\frac{1}{3}} ]$$

$${b}^{*} = 200 [ {( \frac{Y}{Yn} )}^{\frac{1}{3}} - {( \frac{Z}{Zn} )}^{\frac{1}{3}} ]$$

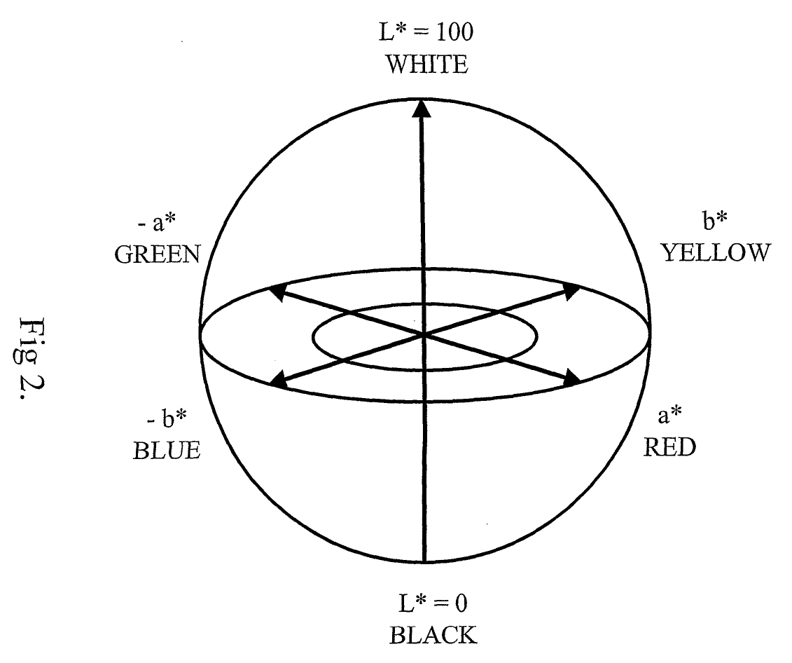

The trimulus values Xn, Yn, Zn are those of the normally white objective-colours stimulus. The L* value is the brightness from black to white, the a* value goes from green to red and the b* value is blue to yellow, see also FIG. 2.

The perceptually linear colour difference formulas between two colours.
ΔE={square root over ((ΔL)²+(Δa)²+(Δb)²))}

The L*, a* and b*-values were in this case measured using a Minolta Spectrofotometer CM-2500d 10° D65. The settings were as follows:

| | |
|---|---|
| Mask/Gloss | M/SCI |
| UV Setting | UV 100% |
| ILLUMINANT1 | D65 |
| OBSERVER | 10° |
| Display | DIFF & ABS |

The L*, a* and b* values were tested three times and the result, which is presented in Table 3, constitutes an average of these three test results.

TABLE 3

| Sample | L* | a* | b* | ΔE |
|---|---|---|---|---|
| 1 | 47 | 40 | 24 | 1.01 |
| 2 | 47 | 41 | 22 | 1.09 |
| 3 | 50 | 42 | 23 | 1.60 |
| 4 | 57 | 26 | 18 | 1.50 |

1. Metal product having a substrate and a coating, wherein the substrate is a metallic material, wherein the coating comprises at least two layers, wherein one layer consists of a metal or metal alloy, and one layer consists of a transparent oxide.

2. Metal product according to claim 1, wherein the layer of a metal or metal alloy is selected from the group consisting of Ag, Al, Au, Co, Cu, Fe, Mn, Si, Sn, Ti, V, W, Zn or Zr, or alloys thereof.

3. Metal product according to claim 1, wherein the transparent oxide is selected from the group consisting of MgO, TiO₂, Al₂O₃ or SiO₂ or a mixture thereof.

4. Metal product according to claim 1, wherein the layer of transparent oxide is thinner than the layer of a metal or metal alloy.

5. Metal product according to claim 1, wherein the substrate is in the form of a strip, foil, wire, fibre, bar or tube.

6. Metal product according to claim 1, wherein the coating comprises a layer of lacquer or paint on top.

7. Method of producing a metal product having a substrate and a coating, wherein the substrate is a metallic material, wherein the coating comprises at least two layers, and wherein one layer consists of a metal or metal alloy, and one layer consists of a transparent oxide, the method comprising: etching the substrate is and thereafter coating by PVD technique, in a continuous roll-to-roll process with a minimum substrate speed of 10 meters per minute, wherein the etching and the coating is performed in-line.

8. Method according to claim 7, wherein the speed of the substrate is at least 25 meters per minute during coating.

9. Method according to claim 7, comprising lacquering or painting the substrate with the coating after the coating process.

10. Use of a product according to claim 1 in the manufacturing of customer related applications, such as outdoor life, sea life and sport applications, household equipment, door handles, camera equipments, mobile phones and other telecom applications, knifes, saws, shaving equipment, or applications for personal belongings and care, like watches, glasses, cosmetic applications, button and zippers in clothing, perfume bottles or the like.

11. A consumer good comprising a metal product having a substrate and a coating, wherein the substrate is a metallic material, wherein the coating comprises at least two layers, and wherein a first layer consists of a metal or metal alloy and a second layer consists of a transparent oxide.

12. The consumer good according to claim 11, wherein the consumer good is equipment for outdoor life, sea life or sport applications.

13. The consumer good according to claim 1 1, wherein the consumer good is household equipment.

14. The consumer good according to claim 11, wherein the consumer good is a door handle.

15. The consumer good according to claim 1 1, wherein the consumer good is camera equipment.

16. The consumer good according to claim 11, wherein the consumer good is a mobile phone or a telecom device.

17. The consumer good according to claim 11, wherein the consumer good is a knife, saw, or a shaving equipment.

18. The consumer good according to claim 11, wherein the consumer good is part of an article of clothing or an accessory.

19. The consumer good according to claim 18, wherein the accessory includes watches or glasses.

20. The consumer good according to claim 11, wherein the consumer good is a cosmetic packaging or a perfume container.
